(19) United States
(12) Patent Application Publication
(10) Pub. No.: US 2024/0342835 A1
(43) Pub. Date: Oct. 17, 2024

(54) METHOD FOR MANUFACTURING CHIPS

(71) Applicant: DISCO CORPORATION, Tokyo (JP)

(72) Inventors: Hayato IGA, Tokyo (JP); Hayato TANAKA, Tokyo (JP)

(21) Appl. No.: 18/616,457

(22) Filed: Mar. 26, 2024

(30) Foreign Application Priority Data
Apr. 13, 2023 (JP) 2023-065812

(51) Int. Cl. B23K 26/53; B23K 26/00; B23K 101/40; H01L 21/304; H01L 21/683; H01L 21/78

(52) U.S. Cl. CPC B23K 26/53; B23K 26/0093; H01L 21/304; H01L 21/6836; H01L 21/78; B23K 2101/40; H01L 2221/68327

(57) ABSTRACT

Disclosed is a method for manufacturing chips by removing, from a workpiece with devices formed on a side of its front surface, first to-be-removed portions located around the devices and second to-be-removed portions located on a side of its back surface with respect to the devices. This method includes an internal processing step of irradiating the first to-be-removed portions with a laser beam to form modified regions there, and cracks spreading from the modified regions such that each crack reaches corresponding one of the second to-be-removed portions through corresponding one of intermediate portions located between the devices and the second to-be-removed portions, a first removal step of removing the first to-be-removed portions, and a second removal step of grinding and removing the second to-be-removed portions and using the cracks as boundaries to separate, from the chips, their back surface side peripheral edge portions.

### BACKGROUND OF THE INVENTION

### Field of the Invention

The present invention relates to a method for manufacturing a plurality of chips by removing, from a workpiece with a plurality of devices formed on a side of a front surface thereof, first to-be-removed portions located around the respective devices and second to-be-removed portions located on a side of a back surface of the workpiece with respect to the respective devices. The chips are thinner than the workpiece.

### Description of the Related Art

Chips of devices such as integrated circuits (ICs) are essential elements in a variety of electronic equipment such as mobile phones and personal computers. These chips are manufactured, for example, by dividing a workpiece such as a wafer, on a side of a front surface on which a plurality of devices are formed, along boundaries of the devices.

With a view to achieving downsizing or the like of various kinds of electronic equipment including a number of chips, a workpiece and/or a plurality of chips manufactured from the workpiece may be ground. Chips may be manufactured, for example, by forming grooves on a side of a front surface of the workpiece at its parts located around the respective devices, and then grinding a side of a back surface of the workpiece until the workpiece is divided using the grooves as boundaries.

In this case, the chips to be manufactured by dividing the workpiece are also ground slightly on sides of their back surfaces. Concomitantly with this grinding, the chips may be chipped away at their back surface side peripheral edge portions. If this is the case, a problem may arise in that the chips may be reduced in flexural strength.

With the foregoing problem in view, it has been proposed to irradiate the peripheral edge portions with a laser beam such that the chips are chamfered on the sides of the back surfaces (see, for example, Japanese Patent Laid-open No. 2004-228218). This removes the back surface side peripheral edge portions where chipping exists, thereby making it possible to suppress reduction in flexural strength of the chips.

### SUMMARY OF THE INVENTION

However, if the back surface side peripheral edge portions of the chips are irradiated with the laser beam, there is a potential problem that thermal damage may remain on the chips. In view of this potential problem, the present invention has, as an object thereof, the provision of a method for manufacturing chips, which can reduce thermal damage on chips and can also suppress the reduction of the flexural strength of the chips.

In accordance with an aspect of the present invention, there is provided a method for manufacturing a plurality of chips by removing, from a workpiece with a plurality of devices formed on a side of a front surface thereof, first to-be-removed portions located around the respective devices and second to-be-removed portions located on a side of a back surface of the workpiece with respect to the respective devices. The chips are thinner than the workpiece. The method includes an internal processing step of irradiating the first to-be-removed portions with a laser beam of a wavelength having transmissivity for the workpiece to form a plurality of modified regions located in the first to-be-removed portions, respectively, and a plurality of cracks spreading from the modified regions, respectively, so that each crack reaches corresponding one of the second to-be-removed portions through corresponding one of intermediate portions located between the devices and the second to-be-removed portions, a first removal step of, after the internal processing step, removing the first to-be-removed portions, and a second removal step of, after the first removal step, grinding and removing the second to-be-removed portions and using the cracks as boundaries to separate, from the chips, back surface side peripheral edge portions thereof.

In the internal processing step, the laser beam may preferably be split to form a plurality of focal points, and the workpiece may preferably be irradiated with the laser beam such that the focal points are formed at locations different from one another in corresponding one of a thickness direction of the workpiece and directions orthogonal to the thickness direction.

The method may preferably further include, before the internal processing step, after the internal processing step and before the first removal step, or after the first removal step and before the second removal step, a bonding step of bonding the devices to a support substrate such that the second to-be-removed portions are exposed.

In the manufacturing method of this invention, the first to-be-removed portions in the workpiece, the first to-be-removed portions being located around the respective devices, are irradiated with the laser beam, but portions that remain as the chips are not irradiated with the laser beam. In this method, chips reduced in thermal damage compared with chips irradiated with a laser beam at their back surface side peripheral edge portions can be provided accordingly.

In this method, when the second to-be-removed portions located on the side of the back surface with respect to the devices in the workpiece are ground and removed, the back surface side peripheral edge portions of the respective chips are separated from the chips using, as boundaries, the cracks spreading from the modified regions, respectively, so that each crack reaches corresponding one of the second to-be-removed portions through corresponding one of intermediate portions located between the devices and the second to-be-removed portions.

In other words, even if, concomitantly with grinding, the back surface side peripheral edge portions of chips are chipped away, the portions where the chipping exists are removed in this method. In this method, chips suppressed in reduction of flexural strength compared with those chipping at their back surface side peripheral edge portions can be provided accordingly.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1A is a perspective view schematically depicting an example of a workpiece for use in manufacture of a plurality of chips;

FIG. 1B is a cross-sectional view schematically depicting the workpiece of FIG. 1A;

FIG. 2 is a flow chart schematically illustrating a method according to a first embodiment of the present invention for manufacturing a plurality of chips, which are thinner than the workpiece of FIG. 1A, by removing a plurality of first to-be-removed portions and a plurality of second to-be-removed portions from the workpiece.

FIG. 3A is a perspective view schematically depicting an example of a frame unit including the workpiece of FIG. 1A;

FIG. 3B is a cross-sectional view schematically depicting the frame unit of FIG. 3A;

FIG. 4 is a perspective view schematically depicting how an example of an internal processing step in the method of FIG. 2 is performed;

FIG. 5 is a diagram schematically depicting a laser beam irradiation unit depicted in FIG. 4 and an example of laser beamlets applied from the laser beam irradiation unit;

FIG. 6 is an enlarged fragmentary cross-sectional view schematically depicting a portion of the frame unit of FIG. 3A which is being irradiated with the laser beamlets of FIG. 5;

FIG. 7A is a perspective view schematically depicting the frame unit of FIG. 3A including the workpiece having a front surface from which a protective tape has been peeled off;

FIG. 7B is a cross-sectional view schematically depicting the frame unit of FIG. 7A;

FIG. 8 is a partly cross-sectional side view schematically depicting how a first example of a first removal step in the method of FIG. 2 is performed;

FIG. 9 is an enlarged fragmentary cross-sectional view schematically depicting a portion of the frame unit of FIG. 3A in which a groove has been formed;

FIG. 10A is a perspective view schematically depicting a plurality of chips with a dicing tape peeled off from back surfaces thereof and with a protective tape bonded to front surfaces thereof;

FIG. 10B is a cross-sectional view schematically depicting the chips of FIG. 10A;

FIG. 11 is a partly cross-sectional side view schematically depicting how an example of a second removal step in the method of FIG. 2 is performed;

FIG. 12 is a cross-sectional view schematically depicting the chips thinned with the protective tape bonded to the front surfaces thereof;

FIG. 13 is a partly cross-sectional side view schematically depicting how a second example of the first removal step in the method of FIG. 2 is performed;

FIG. 14 is an enlarged fragmentary cross-sectional view schematically depicting a portion of the frame unit of FIG. 3A in which a groove has been formed with a bottom surface thereof located in the workpiece;

FIG. 15 is a flow chart schematically illustrating a method according to a second embodiment of the present invention for manufacturing a plurality of chips, which are thinner than a workpiece, by removing a plurality of first to-be-removed portions and a plurality of second to-be-removed portions from the workpiece;

FIG. 16A is a cross-sectional view schematically depicting a stack formed by bonding the workpiece to a support substrate in a bonding step of the method according to the second embodiment;

FIG. 16B is a cross-sectional view schematically depicting the stack including the workpiece of which a side of a back surface has been ground in a preliminary grinding step of the method according to the second embodiment;

FIG. 16C is a cross-sectional view schematically depicting the stack including the workpiece in which a plurality of cracks have been formed in an internal processing step of the method according to the second embodiment;

FIG. 17 is a cross-sectional view schematically depicting how an example of a first removal step of the method according to the second embodiment is performed;

FIG. 18A is an enlarged fragmentary cross-sectional view schematically depicting a portion of the stack of FIG. 16A in which a groove has been formed; and

FIG. 18B is a cross-sectional view schematically depicting a stack that is manufactured in a second removal step of the method according to the second embodiment and that includes a plurality of chips.

### DETAILED DESCRIPTION OF THE PREFERRED EMBODIMENTS

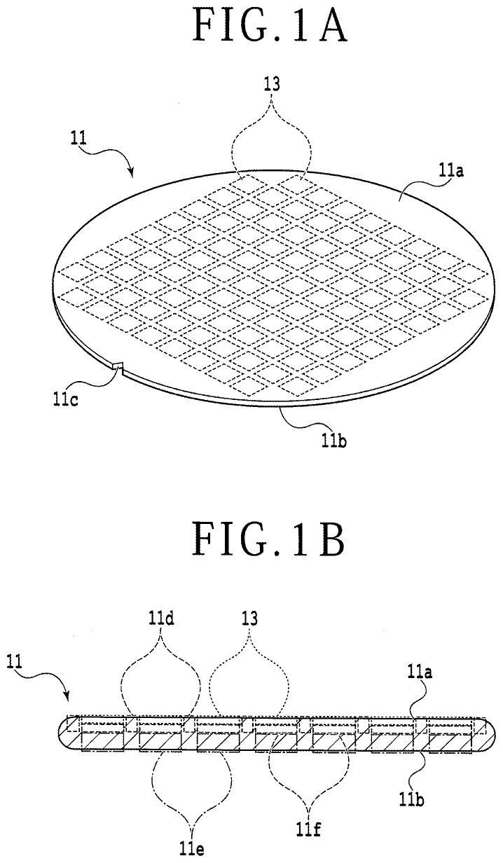

With reference to the attached drawings, a description will be made about first and second embodiments of the present invention. FIG. 1A is a perspective view schematically depicting an example of a workpiece for use in manufacture of a plurality of chips. FIG. 1B is a cross-sectional view schematically depicting the workpiece of FIG. 1A.

A workpiece 11 depicted in FIGS. 1A and 1B is, for example, a disk-shaped wafer including a front surface 11a and a back surface 11b, which are parallel to each other, and made from a semiconductor material, such as single-crystal silicon, as a base material. In a side surface of the workpiece 11, a notch 11c is formed to indicate a specific crystal orientation of the semiconductor material as its base material.

On a side of the front surface 11a of the workpiece 11, a plurality of devices 13 are formed. The devices 13 are arranged in a matrix pattern. Boundaries of the devices 13 hence extend in a grid pattern. By partly removing the workpiece 11, a plurality of chips each of which is thinner than the workpiece 11 are manufactured.

Described specifically, the chips are manufactured by removing, from the workpiece 11, a plurality of first to-be-removed portions 11d located around the respective devices 13 and a plurality of second to-be-removed portions 11e located on a side of the back surface 11b of the workpiece 11 with respect to the devices 13.

The first to-be-removed portions 11d are portions including the boundaries of the devices 13, and extend in the grid pattern. It is to be noted that a plurality of linear portions included in the first to-be-removed portions 11d are also called “scribe lines,” respectively.

The second to-be-removed portions 11e exist in a matrix pattern like the devices 13. Between the second to-be-removed portions 11e and the devices 13, intermediate portions 11f also exist, respectively.

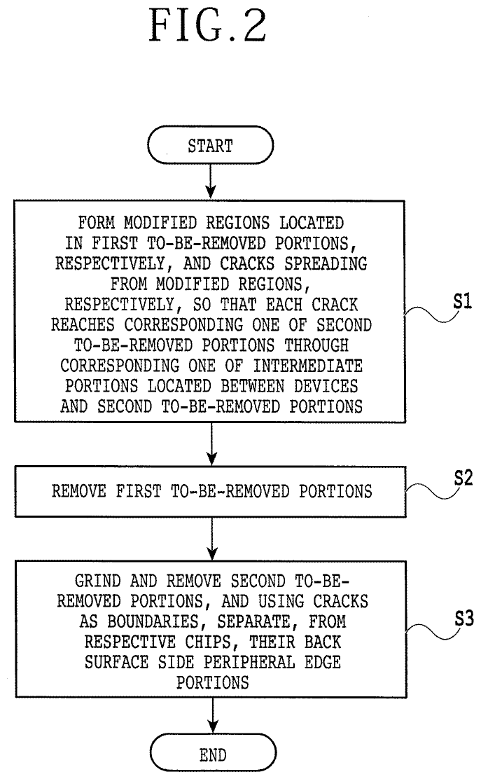

FIG. 2 is a flow chart schematically illustrating a method according to the first embodiment of the present invention for manufacturing a plurality of chips, which are thinner than the workpiece 11, by removing the first to-be-removed portions 11d and the second to-be-removed portions 11e from the workpiece 11.

In the method of the first embodiment, there are formed a plurality of modified regions located in the first to-be-removed portions 11d, respectively, and a plurality of cracks spreading from the modified regions, respectively, so that each crack reaches corresponding one of the second to-be-removed portions 11e through corresponding one of intermediate portions 11f located between the devices 13 and the second to-be-removed portions 11e, respectively (internal processing step S1).

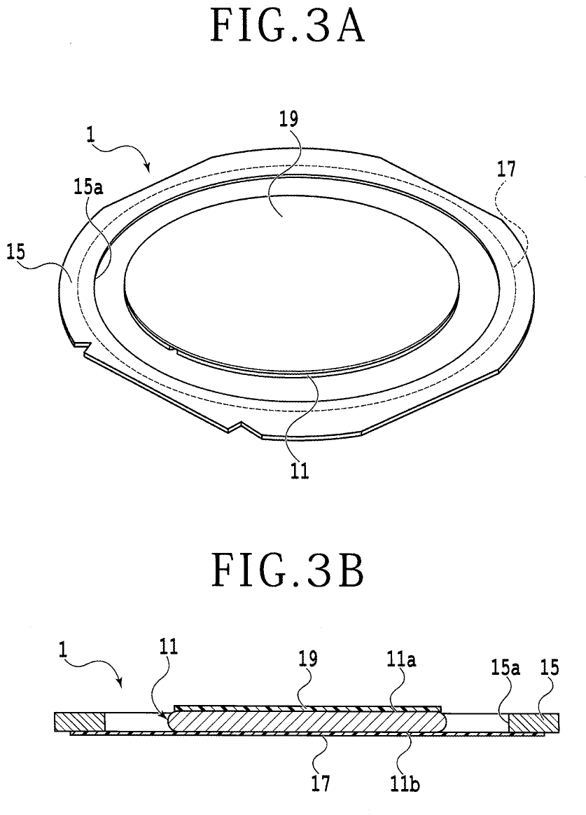

This internal processing step S1 is performed, for example, by irradiating a frame unit, which includes the workpiece 11, with a laser beam in a laser processing machine. FIG. 3A is a perspective view schematically depicting an example of the frame unit including the workpiece 11, and FIG. 3B is a cross-sectional view schematically depicting the frame unit of FIG. 3A.

A frame unit 1 depicted in FIGS. 3A and 3B has an annular frame 15 with a circular opening 15a formed therein. The frame 15 is made, for example, from a metal such as aluminum (Al), to one side of which a disk-shaped dicing tape 17 having a greater diameter than the opening 15a is bonded at an outer peripheral region thereof.

The dicing tape 17 has, for example, a film-shaped base material layer having flexibility, and a self-adhesive layer (glue layer) disposed on one side (a surface on a side of the frame 15) of the base material layer. Described specifically, this base material layer is made from a polyolefin (PO), polypropylene (PP), polyethylene terephthalate (PET), polyvinyl chloride (PVC), polystyrene (PS), or the like. On the other hand, the self-adhesive layer is made from an ultraviolet curable silicone rubber, an acrylic material, an epoxy material, or the like.

The back surface 11b of the workpiece 11, specifically, the second to-be-removed portions 11e are bonded to a central region of the dicing tape 17 so as to position the workpiece 11 in the opening 15a.

Further, a disk-shaped protective tape 19 having substantially the same diameter as that of the workpiece 11 is bonded to the front surface 11a of the workpiece 11, specifically, to the devices 13, to protect the devices 13. This protective tape 19 has, for example, a construction similar to that of the dicing tape 17.

It is to be noted that, in the frame unit 1, the dicing tape 17 may be replaced to a sheet including no self-adhesive layer. This sheet is made, for example, from a material similar to that of the base material layer of the dicing tape 17, and is thermocompression-bonded to the back surface 11b of the workpiece 11, specifically, to the second to-be-removed portions 11e and the one side of the frame 15.

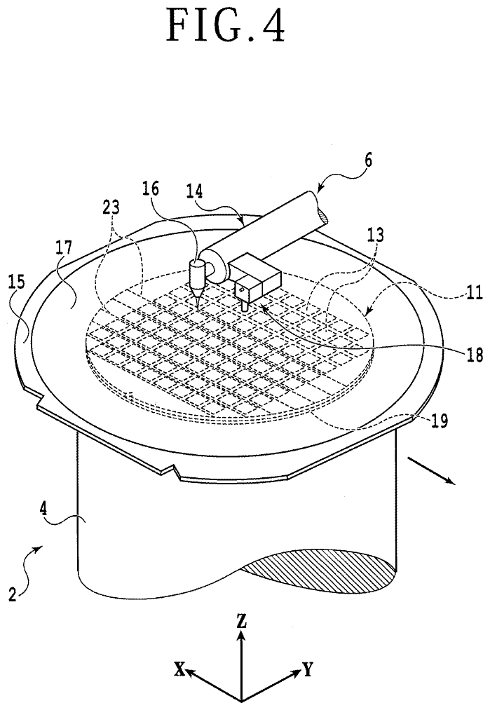

FIG. 4 is a perspective view schematically depicting how an example of the internal processing step S1 is performed. It is to be noted that, in FIG. 4, an X-axis direction and a Y-axis direction are orthogonal to each other on a horizontal plane, and a Z-axis direction is perpendicular to the X-axis direction and the Y-axis direction (a vertical direction).

A laser processing machine 2 depicted in FIG. 4 has a chuck table 4. This chuck table 4 has a disk-shaped frame body having a diameter greater than that of the workpiece 11. This frame body has a disk-shaped bottom wall and a cylindrical side wall disposed upright from an outer peripheral portion of the bottom wall.

On a side of an upper surface of the frame body, a disk-shaped recessed portion is therefore defined by the bottom wall and the side wall. A disk-shaped porous plate is fixed in the recessed portion. In the bottom wall of the frame body, a flow passage is formed opening in a bottom surface of the recessed portion and extending through the bottom wall. The porous plate is brought into communication with a suction source such as an ejector via the flow passage.

When the suction source is operated, a suction force is allowed to act on a space in a vicinity of an upper surface of the porous plate. The frame unit 1 is therefore held on an upper surface (holding surface) of the chuck table 4 when the suction source is operated, for example, after the frame unit 1 has been loaded onto the chuck table 4 to place the workpiece 11 on the chuck table 4 via the protective tape 19.

The chuck table 4 is connected to a rotating mechanism including, for example, a pulley, a motor, and the like. When this rotating mechanism is operated, the chuck table 4 is rotated about a straight line extending, as an axis of rotation, through a center of the holding surface of the chuck table 4 and along the Z-axis direction.

The chuck table 4 is also connected to an X-axis direction moving mechanism and a Y-axis direction moving mechanism, each of which includes, for example, a ball screw, a motor, and the like. When the X-axis direction moving mechanism and/or the Y-axis direction moving mechanism is operated, the chuck table 4 is horizontally moved along the X-axis direction and/or the Y-axis direction.

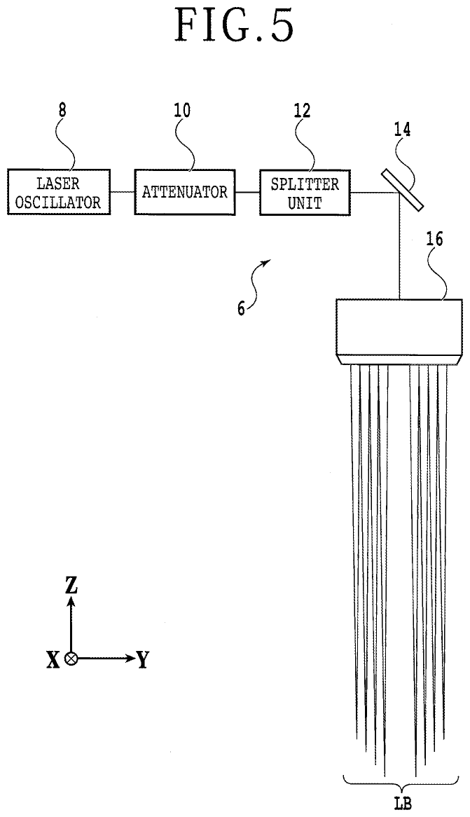

Above the chuck table 4, a laser beam irradiation unit 6 is disposed. FIG. 5 is a diagram schematically depicting the laser beam irradiation unit 6 and an example of a laser beam applied from the laser beam irradiation unit 6. The laser beam irradiation unit 6 has a laser oscillator 8.

This laser oscillator 8 has, for example, Nd:YAG or the like as a laser medium, and applies a pulsed (frequency: 60 kHz, for example) laser beam LB of a wavelength (for example, 1,064 nm or 1,342 nm) having transmissivity for the base material of the workpiece 11.

This laser beam LB is supplied to a splitter unit 12 after its power has been adjusted at an attenuator 10. This splitter unit 12 has, for example, a spatial light modulator including a liquid crystal phase control device called “Liquid Crystal on Silicon (LCOS),” a diffractive optical element (DOE), and/or the like.

The splitter unit 12 splits the laser beam LB such that split laser beams (hereinafter called “laser beamlets”) applied from a below-mentioned irradiation head 16 to a side of the holding surface of the chuck table 4 form a plurality of focal points. For example, this splitter unit 12 splits the laser beam LB so as to satisfy the following conditions in the internal processing step S1.

An even number (four or greater; eight here) of focal points are formed. Except for an interval in a Y-axis direction between the focal points located in pair on a central side, the adjacent paired focal points have a substantially equal interval in the Y-axis direction. The interval between the paired focal points located on the central side is greater than the interval between each adjacent paired focal points other than the paired focal points located on the central side. Positions of the paired focal points located on the central side are at a substantially equal height in the Z-axis direction. The paired focal points located on the central side are lower in height than the remaining focal points.

Among the eight focal points, one of the paired focal points located on the central side to the focal point located on one end in the Y-axis direction, in other words, the four focal points on one side are juxtaposed at equal intervals in the Z-axis direction. Among the eight focal points, the other one of the paired focal points located on the central side to the focal point located on the other end in the Y-axis direction, in other words, the four focal points on the other side are similarly juxtaposed at equal intervals in the Z-axis direction.

The interval in the Z-axis direction between the adjacent paired focal points among the four focal points on the one side and the interval in the Z-axis direction between the adjacent paired focal points among the four focal points on the other side are substantially equal to each other. The interval between the focal point located on the one end and the focal point located on the other end in the Y-axis direction among the eight focal points is slightly smaller than the width of a region located between associated adjacent paired devices 13 in the first to-be-removed portions 11d included in the workpiece 11.

The laser beamlets LB split at the splitter unit 12 are reflected by a mirror 14, and are then introduced into the irradiation head 16. In this irradiation head 16, a condenser lens (not depicted) or the like is accommodated to condense the laser beamlets LB. The laser beamlets LB condensed through the condenser lens are applied toward the holding surface of the chuck table 4, in brief, directly downward.

Further, the irradiation head 16 of the laser beam irradiation unit 6 and an optical system (for example, the mirror 14) for introducing the laser beamlets LB into the irradiation head 16 are connected to a Z-axis direction moving mechanism (not depicted) including, for example, a ball screw, a motor, and the like. When this Z-axis direction moving mechanism is operated, the irradiation head 16 and the like are moved along a vertical direction.

In addition, an imaging unit 18 is disposed on a side of the irradiation head 16 as depicted in FIG. 4. This imaging unit 18 performs imaging using light of a wavelength having transmissivity for the material, which makes up the dicing tape 17, and the base material of the workpiece 11, for example, an infrared ray.

The imaging unit 18 includes, for example, a light source such as a light emitting diode (LED) that applies the infrared ray, an objective lens, and an imaging device such as a charge coupled device (CCD) image sensor or a complementary metal oxide semiconductor (CMOS) image sensor, and images the side of the holding surface of the chuck table 4.

When the internal processing step S1 is performed in the laser processing machine 2, the frame unit 1 is first loaded into the laser processing machine 2 such that the workpiece 11 is placed on the chuck table 4 via the protective tape 19. The suction source that is in communication with the porous plate of the chuck table 4 is then operated. As a consequence, the frame unit 1 is held on the chuck table 4 with the dicing tape 17 directed upward.

The side of the front surface 11a of the workpiece 11 is next imaged by the imaging unit 18. As a consequence, an image is formed in which an array of the devices 13 on the side of the front surface 11a of the workpiece 11 is recognizable. With reference to this image, the chuck table 4 is then rotated such that specific one of the scribe lines included in the first to-be-removed portions 11d of the workpiece 11 becomes parallel to the X-axis direction.

The chuck table 4 is next moved along the X-axis direction and/or Y-axis direction such that the specific one scribe line is positioned in the X-axis direction as seen from the irradiation head 16 in plan view. The irradiation head 16 and the like are then raised or lowered such that the paired focal points located on the central side among the eight focal points, which are formed when the laser beamlets LB are applied directly downward from the irradiation head 16, are positioned slightly higher than the position of a front surface of the opposing first to-be-removed portion 11d.

The laser beam irradiation unit 6 is next operated such that these laser beamlets LB are applied directly downward from the irradiation head 16. The chuck table 4 is then moved along the X-axis direction such that the laser beamlets LB pass from one end to the other end in the X-axis direction of the workpiece 11 along the specific one scribe line.

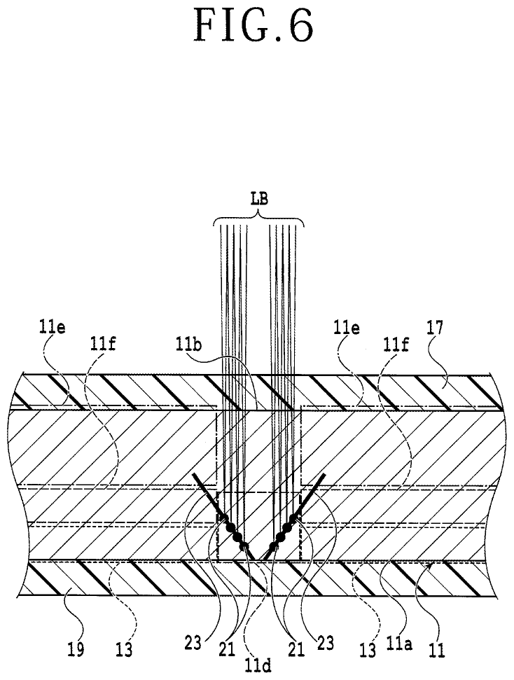

As a consequence, modified regions 21 are formed inside the opposing first to-be-removed portion 11d, centering around the focal points where the laser beamlets LB are focused (see FIG. 6). In the modified regions 21, the crystal structure of the base material of the workpiece 11 is disordered. FIG. 6 is an enlarged fragmentary cross-sectional view schematically depicting a portion of the frame unit 1, which is being irradiated with the laser beamlets LB.

As described above, the laser beamlets LB have been formed through the splitting at the splitter unit 12 such that they satisfy the above-mentioned conditions. Accordingly, eight modified regions 21 are formed inside the opposing first to-be-removed portion 11d.

The eight modified regions 21 are roughly divided into the four modified regions 21 located between their center and the one end in the Y-axis direction, in other words, the four modified regions 21 on one side, and the four modified regions 21 located between their center and the other end in the Y-axis direction, in other words, the four modified regions 21 on the other side.

Further, the four modified regions 21 on the one side and the four modified regions 21 on the other side are linearly aligned and inclined at a predetermined angle with respect to a thickness direction of the workpiece 11 such that, between each two adjacent modified regions 21 on each side, the position of the modified region 21 located on an outer side is higher than the position of the modified region 21 located on an inner side. Furthermore, the four modified regions 21 on the one side and the four modified regions 21 on the other side are, in plan, symmetry with respect to a plane that extends through their center in the Y-axis direction and is parallel to the X-axis direction and Z-axis direction.

When the eight modified regions 21 are formed inside the facing first to-be-removed portion 11d, the volume of the workpiece 11 expands, thereby producing internal stress in the workpiece 11. Cracks 23 then spread from the eight modified regions 21, respectively, so that the internal stress is relaxed.

Here, the cracks 23 are prone to spread toward the adjacent modified regions 21. Described specifically, the cracks tend to spread such that they are inclined at the predetermined angle with respect to the thickness direction of the workpiece 11. As a result, the cracks 23 reach the front surface of the first to-be-removed portion 11d and further reach the second to-be-removed portion 11e through the intermediate portion 11f.

Further, the movement of the chuck table 4 and the operation of the laser beam irradiation unit 6 are repeated such that modified regions 21 and cracks 23 are formed in all the first to-be-removed portions 11d of the workpiece 11. By the foregoing, the internal processing step S1 is completed.

It is to be noted that the cracks 23 formed in the internal processing step S1 are not absolutely required to reach the front surfaces of the first to-be-removed portions 11d. The cracks 23 may not be absolutely required to reach the front surfaces of the first to-be-removed portions 11d, for example, if the four modified regions 21 on the one side and the four modified regions 21 on the other side are formed such that the above-described predetermined angle ranges from 60° to smaller than 90°.

This case is preferred in that it facilitates to increase the sizes of back surface side peripheral edge portions to be separated from the respective chips manufactured from the workpiece 11. In this case, however, the cracks 23 become prone to spread to the devices 13. On the other hand, the formation of the cracks 23 so as to reach the front surfaces of the first to-be-removed portions 11d is preferred in that spreading of the cracks 23 to the devices can be suppressed.

After the internal processing step S1 has been performed, the first to-be-removed portions 11d are removed (first removal step S2). This first removal step S2 is performed, for example, in a cutting machine by cutting the frame unit 1 including the workpiece 11 from the front surface 11a from which the protective tape 19 has been peeled off.

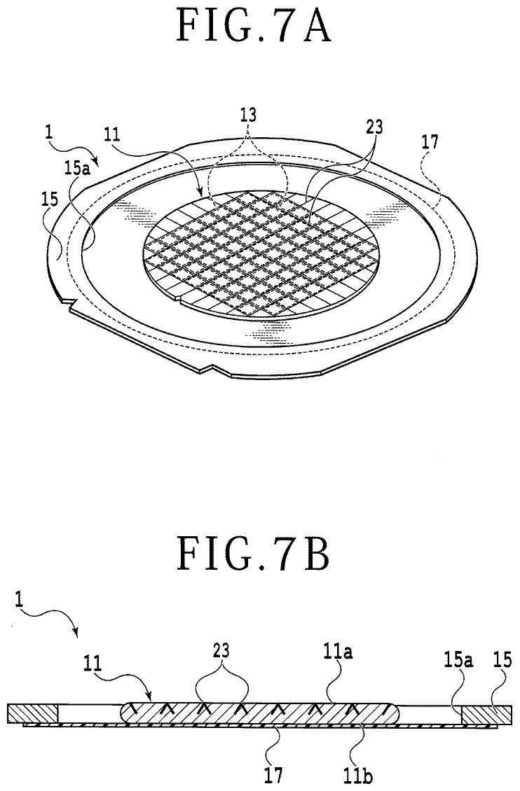

FIG. 7A is a perspective view schematically depicting the frame unit 1 including the workpiece 11 from the front surface 11a from which the protective tape 19 has been peeled off, and FIG. 7B is a cross-sectional view schematically depicting the frame unit 1 of FIG. 7A.

In the frame unit 1 depicted in FIGS. 7A and 7B, the cracks 23 which are postulated to have existed along the first to-be-removed portions 11d of the workpiece 11 are formed on the side of the front surface 11a. These cracks 23 spread inside the workpiece 11 such that they are inclined to the thickness direction of the workpiece 11.

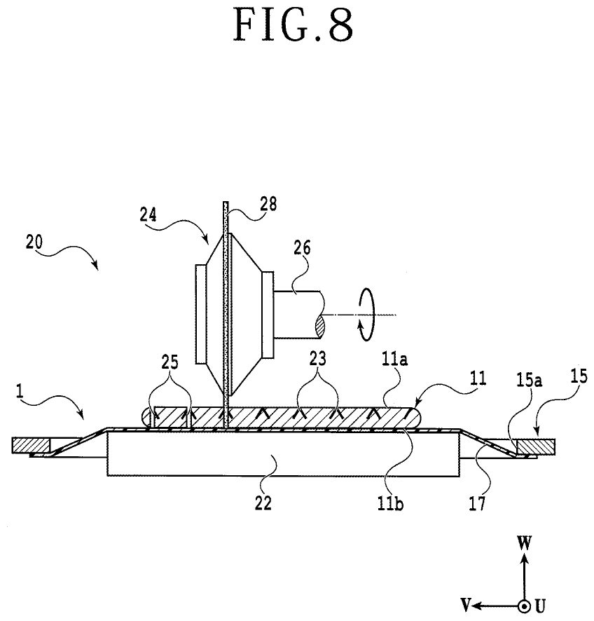

FIG. 8 is a partly cross-sectional side view schematically depicting how a first example of the first removal step S2 is performed. It is to be noted that, in FIG. 8, a U-axis direction and a V-axis direction are orthogonal to each other on a horizontal plane, and a W-axis direction is perpendicular to the U-axis direction and the V-axis direction (a vertical direction).

A cutting machine 20 depicted in FIG. 8 has a chuck table 22. This chuck table 22 has a similar construction to the chuck table 4 depicted in FIG. 4. Around the chuck table 22, a plurality of clamps (not depicted) are disposed.

These clamps are disposed at substantially equal angular intervals along a peripheral direction of the chuck table 22. When the frame unit 1 is held on the chuck table 22, the frame 15 is grasped by the clamps at a position lower than a holding surface of the chuck table 22.

The chuck table 22 and clamps are connected to a rotating mechanism including, for example, a pulley, a motor, and the like. When this rotating mechanism is operated, the chuck table 22 is rotated about a straight line extending, as an axis of rotation, through a center of the holding surface of the chuck table 22 and along the W-axis direction.

The chuck table 22 is also connected to a U-axis direction moving mechanism including, for example, a ball screw, a motor, and the like. When this U-axis direction moving mechanism is operated, the chuck table 22 is moved along the U-axis direction.

Above the chuck table 22, a cutting unit 24 is disposed. This cutting unit 24 has a cylindrical spindle 26 extending along the V-axis direction. The spindle 26 is connected at a proximal end portion thereof to a rotary drive source (not depicted) such as a motor, and, on a distal end portion of the spindle 26, an annular cutting blade 28 is fitted.

When the rotary drive source is operated, the cutting blade 28 is rotated along with the spindle 26 using, as an axis of rotation, a straight line along the V-axis direction. The cutting blade 28 is fitted on the spindle 26 such that the straight line as the axis of rotation for the spindle 26 extends through a center of the cutting blade 28.

The cutting unit 24 is connected to a V-axis direction moving mechanism and a W-axis direction moving mechanism, each of which includes, for example, a ball screw, a motor, and the like. When the V-axis direction moving mechanism is operated, the cutting unit 24 is moved along the V-axis direction. When the W-axis direction moving mechanism is operated, the cutting unit 24 is moved along the W-axis direction.

When the first removal step S2 is performed in the cutting machine 20, the frame unit 1 is first loaded into the cutting machine 20 such that the workpiece 11 is placed on the chuck table 22 via the dicing tape 17.

Next, a suction source that is in communication with a porous plate of the chuck table 22 is operated, and, at the same time, the frame 15 is grasped by the clamps. As a consequence, the frame unit 1 is held on the chuck table 22 with the front surface 11a of the workpiece 11, specifically, the devices 13 and the first to-be-removed portions 11d exposed.

The chuck table 22 is next rotated such that specific one of the scribe lines included in the first to-be-removed portions 11d becomes parallel to the U-axis direction. The chuck table 22 is then moved along the U-axis direction such that the specific one scribe line is positioned along the U-axis direction as seen from the cutting blade 28 in plan view, and/or the cutting unit 24 is moved along the V-axis direction.

The cutting unit 24 is next raised or lowered such that the lower end of the cutting blade 28 is positioned inside the dicing tape 17, specifically, positioned higher than the holding surface of the chuck table 22 and lower than the back surface 11b of the workpiece 11. The rotary drive source connected to the spindle 26 is then operated so as to rotate the cutting blade 28.

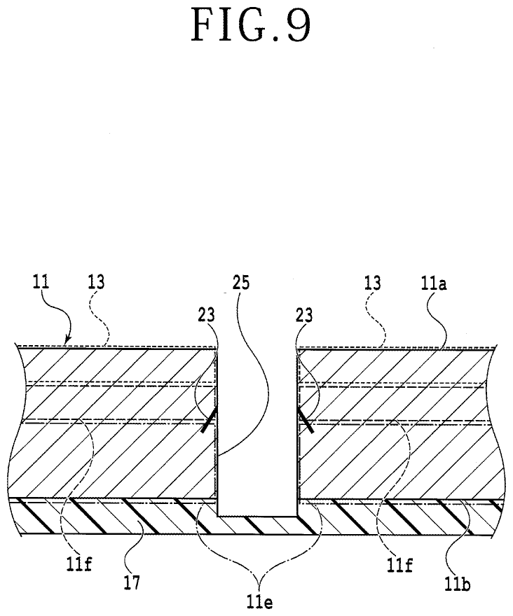

The chuck table 22 is next moved along the U-axis direction such that the cutting blade 28 passes from one end to the other end in the U-axis direction of the workpiece 11 along the specific one scribe line. As a consequence, a linear groove 25 is formed through the workpiece 11 in the frame unit 1, with a bottom surface thereof located in the dicing tape 17 (see FIG. 9). FIG. 9 is an enlarged fragmentary cross-sectional view schematically depicting a portion of the frame unit 1 in which the groove 25 has been formed.

Concomitantly with the formation of the groove 25, a linear region of the first to-be-removed portion 11d, the linear region extending along the specific one scribe line, is removed along with the modified regions 21 and the cracks 23 included in the region. However, portions of the cracks 23, the portions spreading from the region and being formed in the adjacent intermediate portion 11f and the second to-be-removed portions 11e, are allowed to remain.

Further, the relative movement of the chuck table 22 and the cutting unit 24 and the rotation of the cutting blade 28 are repeated such that all the first to-be-removed portions 11d of the workpiece 11 are removed along with the modified regions 21 and cracks 23 included therein. As a result, the workpiece 11 is divided, whereby the chips are manufactured each with a thickness substantially equal to that of the workpiece 11.

After the first removal step S2, the second to-be-removed portions 11e are ground and removed, and, from the chips, their back surface side peripheral edge portions are separated using the cracks 23 as boundaries (second removal step S3). This second removal step S3 is performed, for example, in a grinding machine by grinding the chips from the back surfaces, specifically, the second to-be-removed portions 11e from which the dicing tape 17 has been peeled off.

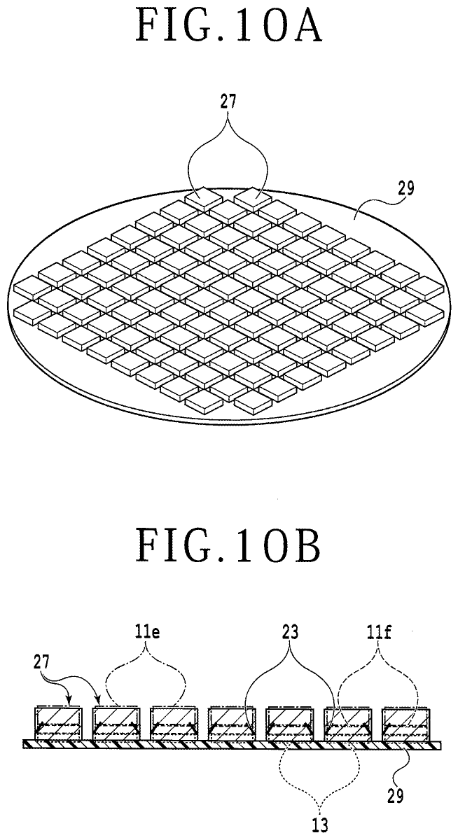

FIG. 10A is a perspective view schematically depicting the chips obtained as described above, and FIG. 10B is a cross-sectional view schematically depicting the chips of FIG. 10A. To front surfaces of the respective chips 27 depicted in FIGS. 10A and 10B, specifically, to the devices 13, a disk-shaped protective tape 29 is bonded. This protective tape 29 has, for example, a similar construction to the dicing tape 17.

It is to be noted that, in the second removal step S3, the chips 27 included in a frame unit may be ground. This frame unit has, for example, a disk-shaped protective tape bonded at a central region thereof to the front surfaces of the respective chips 27, specifically, to the devices 13, and an annular frame bonded to an outer peripheral region of the protective tape.

The protective tape and frame included in this frame unit have, for example, similar constructions to the dicing tape 17 and the frame 15, respectively. The use of the above-described frame unit is preferred in that handling of the chips 27, for example, the loading and unloading of the chips 27 into and from the grinding machine is facilitated when the chips 27 included in the frame unit are ground in the second removal step S3.

In the case that the above-described frame unit is used, however, there is a need to grasp the frame, for example, by a plurality of clamps to avoid grinding of the frame along with the chips 27. In contrast, the grinding of chips 27, which are depicted in FIGS. 10A and 10B, in the second removal step S3 is preferred in that the second removal step S3 can also be performed even in a grinding machine including no clamps.

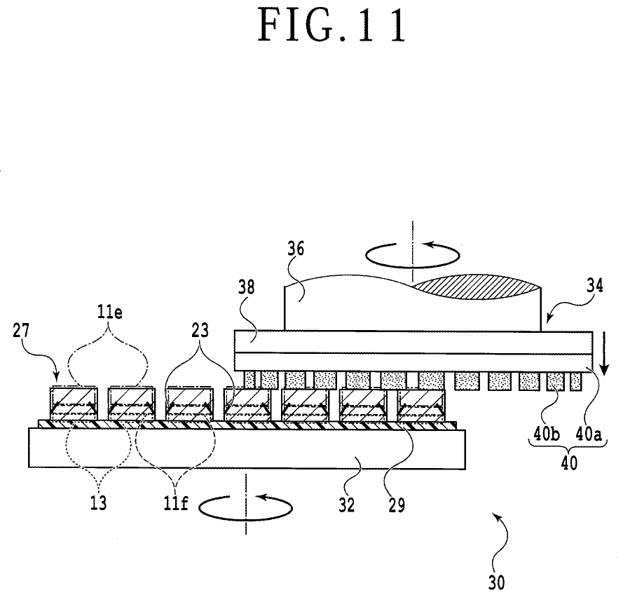

FIG. 11 is a partly cross-sectional side view schematically depicting how an example of the second removal step S3 is performed. A grinding machine 30 depicted in FIG. 11 has a chuck table 32. This chuck table 32 has a similar construction to the chuck table 4 depicted in FIG. 4. The chuck table 32 may, however, have a holding surface of a shape corresponding to a side surface of a circular cone, a center of which slightly protrudes upward relative to an outer circumference.

The chuck table 32 is connected to a rotating mechanism including, for example, a pulley, a motor, and the like. When this rotating mechanism is operated, the chuck table 32 is rotated about a straight line extending, as an axis of rotation, through a center of the holding surface of the chuck table 32 and along a peripheral direction thereof.

The chuck table 32 is also connected to a swing mechanism including, for example, a turn table, a motor, and the like. When this swing mechanism is operated, the chuck table 32 is caused to swing on a horizontal plane.

Above the chuck table 32, a grinding unit 34 is disposed. This grinding unit 34 has a spindle 36 extending in a direction substantially parallel to a vertical direction. On a distal end portion (lower end portion) of the spindle 36, a disk-shaped wheel mount 38 made from stainless steel or the like is fixed at an upper surface thereof.

On a lower surface of the wheel mount 38, an annular grinding wheel 40 that has an outer diameter substantially equal to a diameter of the wheel mount 38 is secured. The grinding wheel 40 has an annular wheel base 40a. This wheel base 40a is made, for example, from stainless steel or the like. On a side of a lower surface of the wheel base 40a, a plurality of grinding stones 40b are arranged at substantially equal intervals along a peripheral direction of the wheel base 40a.

Further, the spindle 36 is connected at a proximal end portion (upper end portion) thereof to a rotary drive source such as a motor. When this rotary drive source is operated, the wheel mount 38 and the grinding wheel 40 are rotated along with the spindle 36.

Further, the grinding unit 34 is connected to a vertical moving mechanism including, for example, a ball screw, a motor, and the like. When this vertical moving mechanism is operated, the grinding unit 34 is moved along the vertical direction.

When the second removal step S3 is performed in the grinding machine 30, the chips 27 are loaded into the grinding machine 30 such that the chips 27 are placed on the chuck table 32 via the protective tape 29. A suction source that is in communication with a porous plate of the chuck table 32 is next operated. As a consequence, the chips 27 are held on the chuck table 32 with the second to-be-removed portions 11e directed upward.

The swing mechanism connected to the chuck table 32 is next operated such that, when the grinding wheel 40 is rotated, the grinding stones 40b draw a trajectory located right above a center of the protective tape 29. The rotary drive source connected to the spindle 36 is then operated so as to rotate the grinding wheel 40, and, at the same time, the rotating mechanism connected to the chuck table 32 is operated so as to rotate the chuck table 32.

With both the grinding wheel 40 and the chuck table 32 being rotated, the grinding unit 34 is next lowered such that the grinding stones 40b are brought into contact at lower surfaces thereof with the back surfaces of the chips 27, specifically, the second to-be-removed portions 11e. As a consequence, grinding of sides of the back surfaces of the chips 27 is started, and the second to-be-removed portions 11e are gradually removed.

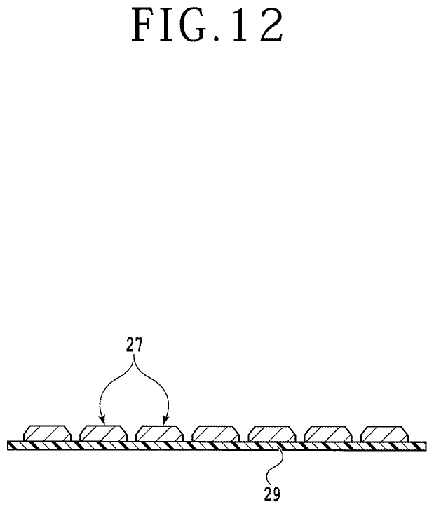

The sides of the back surfaces of the chips 27 are ground further until the second to-be-removed portions 11e are removed in their entirety. As a result, the chips 27 are manufactured, each with a thickness reduced by thinning (see FIG. 12). FIG. 12 is a cross-sectional view schematically depicting the chips 27 thinned with the protective tape 29 bonded to the front surfaces thereof.

When the second to-be-removed portions 11e are ground until the cracks 23 are exposed at the back surfaces of the respective chips 27, the chips 27 are cleaved using the cracks 23 as boundaries. In other words, back surface side peripheral edge portions of the respective chips 27 are separated from the individual chips 27 during this grinding. By the foregoing, the second removal step S3 is completed.

In the method of the first embodiment as depicted in FIG. 2, the first to-be-removed portions 11d in the workpiece 11, the first to-be-removed portions 11d being located around the respective devices 13, are irradiated with the laser beamlets LB, but the portions that remain as the chips 27 are not irradiated with the laser beamlets LB. In this method, the chips 27 reduced in thermal damage compared with those irradiated with the laser beamlets LB at their back surface side peripheral edge portions can be provided accordingly.

In the method of the first embodiment, when the second to-be-removed portions 11e located on the side of the back surface 11b with respect to the devices 13 in the workpiece 11 are ground and removed, the back surface side peripheral edge portions of the respective chips 27 are separated from the chips 27 using, as boundaries, the cracks 23 spreading from the modified regions 21, respectively, so that each crack reaches corresponding one of the second to-be-removed portions 11e through corresponding one of intermediate portions 11f located between the devices 13 and the second to-be-removed portions 11e, respectively.

In other words, even if, concomitantly with this grinding, the chips 27 are chipped away at their back surface side peripheral edge portions, the portions where the chipping exists are removed in the method of the first embodiment. In the method of the first embodiment, the chips 27 suppressed in reduction of flexural strength compared with those having chipping at their back surface side peripheral edge portions can be provided accordingly.

It is to be noted that the above-mentioned details relate to an embodiment of the present invention, and the present invention are not limited to the above-mentioned details. In the internal processing step S1 of the method according to the first embodiment, for example, the modified regions 21 and the cracks 23 may be formed by applying the laser beamlets LB from the side of the front surface 11a of the workpiece 11.

In this case, it is no longer necessary to perform imaging in the internal processing step S1 using an infrared ray to confirm the array of the devices 13, specifically, the direction of specific one of the scribe lines included in the first to-be-removed portions 11d. This case is therefore preferred in that the internal processing step S1 can be performed using an inexpensive laser processing machine without the imaging unit 18 that performs imaging using the infrared ray.

On the front surfaces of the first to-be-removed portions 11d, test elementary groups (TEGs) or the like may, however, be formed to evaluate the performance of the devices 13. In this case, there is a possible problem in that it is difficult to form the modified regions 21 and the cracks 23 at desired locations.

Here, formation of modified regions 21 and cracks 23 by application of laser beamlets LB from the side of the back surface 11b of the workpiece 11 is preferred in that the formation of the modified regions 21 and the cracks 23 at desired locations is facilitated even when TEGs or the like are formed on the front surfaces of the first to-be-removed portions 11d.

In the internal processing step S1 of the method according to the first embodiment of the present invention, a plurality of (for example, eight in FIG. 6) modified regions 21 included in the linear region along the specific one scribe line in each first to-be-removed portion 11d are not absolutely required to be formed concurrently. Described specifically, after some of the modified regions 21, for example, the above-described four modified regions 21 on the one side have been formed, the remainder, for example, the above-described four modified regions 21 on the other side may be formed.

In other words, in the internal processing step S1 of the method according to the first embodiment, after the linear region has been irradiated with laser beamlets LB formed through splitting so as to form some of the modified regions 21, the linear region may be irradiated with laser beamlets LB formed through splitting so as to form the remaining modified regions 21.

In the internal processing step S1 of the method according to the first embodiment, after the modified regions 21 and the cracks 23 have been formed in the linear region, the linear region may be irradiated again with laser beamlets LB. As a consequence, the modified regions 21 can each be enlarged, and/or the cracks 23 can each be allowed to spread further.

In the first removal step S2 of the method according to the first embodiment, the first to-be-removed portions 11d may be removed by causing the cutting blade 28 to cut in from the side of the back surface 11b of the workpiece 11. In this case, the front surface 11a of the workpiece 11, specifically, the devices 13 are bonded to a dicing tape 17 before the internal processing step S1.

In this case, it is no longer necessary to bond a protective tape 19 to the back surface 11b of the workpiece 11, specifically, to the second to-be-removed portions 11e before the internal processing step S1. This case is therefore preferred in that labor required to bond the protective tape 19 to the second to-be-removed portions 11e and to peel the protective tape 19 from the second to-be-removed portions 11e can be obviated.

In this case, however, imaging with an infrared ray is needed to accurately find the scribe lines included in the first to-be-removed portions 11d of the workpiece 11 in the first removal step S2. This case therefore requires to perform the first removal step S2 using an expensive cutting machine that includes an imaging unit similar to the imaging unit 18.

On the other hand, removal of the first to-be-removed portions 11d by causing the cutting blade 28 to cut in from the side of the front surface 11a of the workpiece 11 is preferred in that the first removal step S2 can be performed using an inexpensive cutting machine without an imaging unit similar to the imaging unit 18, for example, the cutting machine 20.

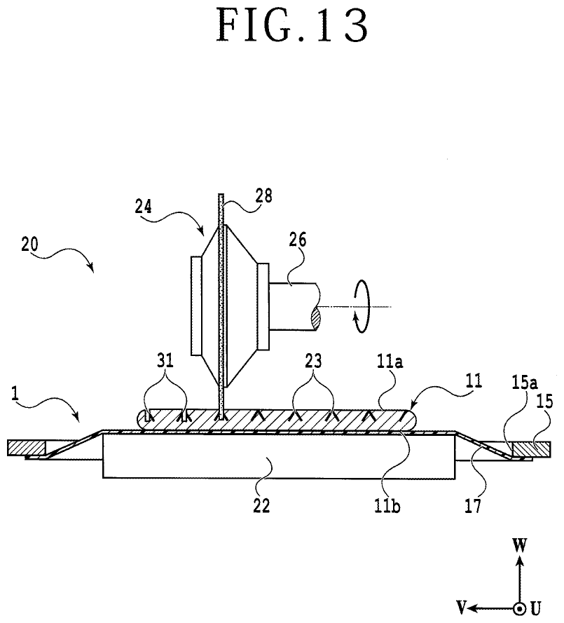

In the first removal step S2 of the method according to the first embodiment, grooves may be formed in the frame unit 1 such that their bottom surfaces are located in the workpiece 11 without extending through the workpiece 11. FIG. 13 is a partly cross-sectional side view schematically depicting how a second example of the first removal step S2 is performed as described above.

This second example of the first removal step S2 is performed by cutting a frame unit 1 (see FIGS. 7A and 7B) in the above-mentioned cutting machine 20. Described specifically, when the second example of the first removal step S2 is performed as described above, the frame unit 1 is first held on the chuck table 22 as mentioned above.

As mentioned above, scribe lines included in first to-be-removed portions 11d are next positioned in the U-axis direction as seen from the cutting blade 28 in plan view. The cutting unit 24 is then raised or lowered such that the lower end of the cutting blade 28 is positioned inside the workpiece 11, specifically, positioned higher than the dicing tape 17 and lower than the first to-be-removed portions 11d of the workpiece 11.

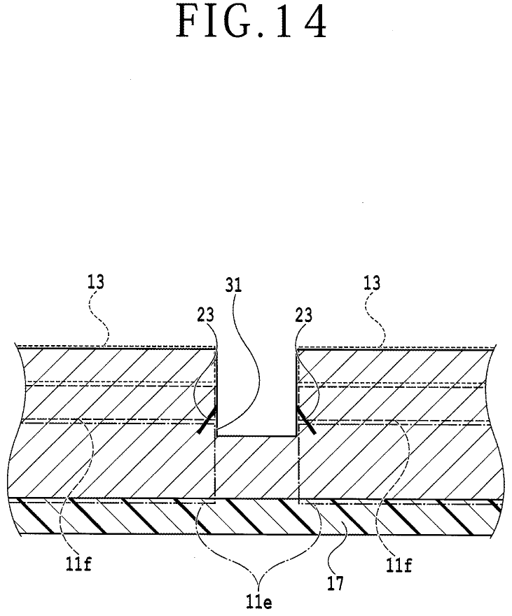

The relative movement of the chuck table 22 and the cutting unit 24 and the rotation of the cutting blade 28 are next repeated as mentioned above. As a consequence, grid-patterned grooves 31 are formed in the frame unit 1 with their bottom surfaces located in the workpiece 11 without extending through the workpiece 11 (see FIG. 14). FIG. 14 is an enlarged fragmentary cross-sectional view schematically depicting a portion of the frame unit 1 in which one of the grooves 31 has been formed.

It is to be noted that, in this first removal step S2, the workpiece 11 is not divided, in other words, chips 27 are not manufactured. In the second removal step S3, the side of the back surface 11b of the workpiece 11 is therefore ground until the workpiece 11 is divided using the grooves 31 as boundaries, whereby the chips 27 are manufactured.

The first removal step S2 of the method according to the first embodiment may also be performed by applying plasma etching to the workpiece 11 on which a mask is disposed so as to cover a plurality of devices 13, in a dry etching system. About an example of a dry etching system for such plasma etching, a description will be made subsequently herein.

The second removal step S3 of the method according to the first embodiment may also be performed by grinding a plurality of chips in which devices 13 are bonded to a support substrate instead of the protective tape 29. Examples of the support substrate include a wafer or the like, which has substantially the same shape as the workpiece 11.

The bonding of the devices 13 to the support substrate may be performed before the internal processing step S1, after the internal processing step S1 and before the first removal step S2, or after the first removal step S2 and before the second removal step S3. In the present invention, the chips 27 may be bonded to the support substrate, or the workpiece 11 before its division into the chips 27 may be bonded to the support substrate, accordingly.

The bonding of the chips 27 to the support substrate is preferred in that, among the chips 27, only those which are good in processed quality can be extracted and bonded. On the other hand, the bonding of the workpiece 11 to the support substrate is preferred in that, owing to its simpler work, sticking, deposition, and the like of contaminants on the chips can be suppressed, and/or the throughput can be improved.

In the method according to the first embodiment, the side of the back surface 11b of the workpiece 11 may also be ground such that the second to-be-removed portions 11e are thinned before the internal processing step S1. This grinding is performed, for example, in the grinding machine 30.

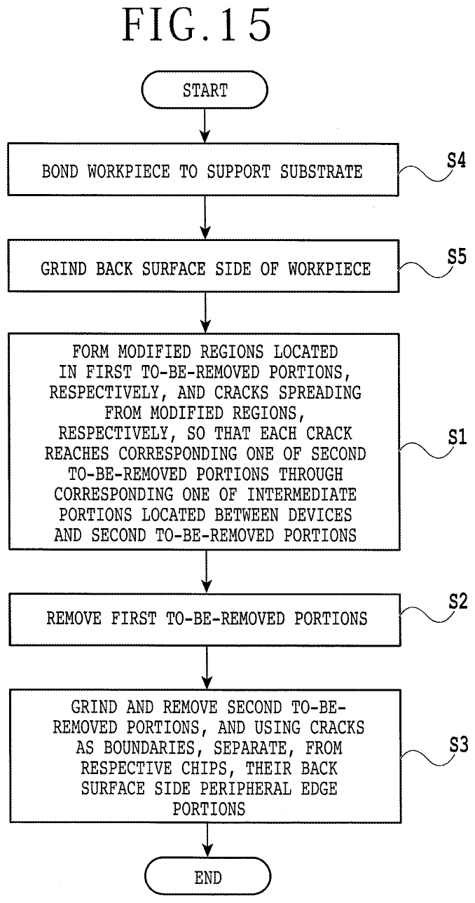

The method according to the first embodiment may also be performed by appropriately combining the above-mentioned details. FIG. 15 is a flow chart schematically illustrating, as the second embodiment, an example of such a manufacturing method of chips.

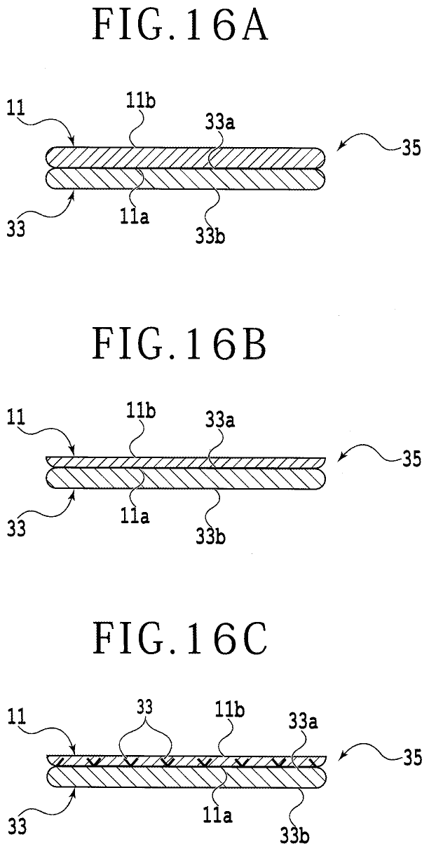

In the method according to the second embodiment, a workpiece 11 is first bonded to a support substrate 33 (bonding step S4). FIG. 16A is a cross-sectional view schematically depicting a stack formed by bonding the workpiece 11 to the support substrate 33 in the bonding step S4.

The support substrate 33 bonded with the workpiece 11 has, for example, a shape similar to that of the workpiece 11. Similarly to the workpiece 11, a plurality of devices may also be formed on a side of a front surface 33a of the support substrate 33.

In the bonding step S4, a front surface 11a of the workpiece 11, specifically, a plurality of devices 13 are bonded to the front surface 33a of the support substrate 33. Described specifically, an adhesive with an acrylic adhesive or epoxy adhesive contained therein is first applied to the front surface 33a of the support substrate 33 in this bonding step S4.

With the support substrate 33 supported on the side of a back surface 33b thereof, the front surface 11a of the workpiece 11 is next pressed against the front surface 33a of the support substrate 33 via the adhesive. As a consequence, a stack 35 is formed including the workpiece 11 bonded to the support substrate 33 such that its back surface 11b is exposed. By the foregoing, the bonding step S4 is completed.

After the bonding step S4, the side of the back surface 11b of the workpiece 11 is ground (preliminary grinding step S5). FIG. 16B is a cross-sectional view schematically depicting the stack 35 including the workpiece 11 of which the side of the back surface 11b has been ground in the preliminary grinding step S5.

This preliminary grinding step S5 is performed by grinding the side of the back surface 11b of the workpiece 11, for example, in the grinding machine 30 until the thickness of the second to-be-removed portion 11e depicted in FIG. 1B, etc. is reduced to ⅓ times to ⅔ times, typically to ½ times. It is to be noted that this grinding is performed as in the above-mentioned second removal step S3, and its detailed description is hence omitted.

After the preliminary grinding step S5, an internal processing step S1 is performed. FIG. 16C is a cross-sectional view schematically depicting the stack 35 including the workpiece 11 in which a plurality of cracks 23 have been formed in the internal processing step S1.

The internal processing step S1 of the method according to the second embodiment is performed by irradiating the stack 35, which includes the workpiece 11 of which the side of the back surface 11b has been ground, with laser beamlets LB, for example, in the laser processing machine 2. It is to be noted that this irradiation with the laser beamlets LB is performed as in the above-mentioned internal processing step S1 of the method according to the first embodiment, and its detailed description is hence omitted.

After the internal processing step S1 of the method according to the second embodiment, a first removal step S2 is performed. This first removal step S2 is performed by applying plasma etching to the stack 35 including the workpiece 11, inside of which the cracks 23 have been formed, for example, in a dry etching system.

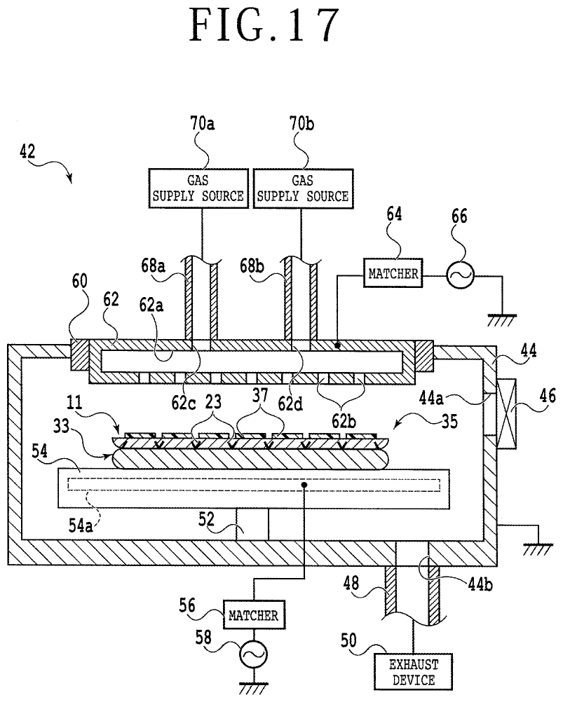

FIG. 17 is a cross-sectional view schematically depicting how an example of the first removal step S2 of the method according to the second embodiment is performed. A dry etching system 42 depicted in FIG. 17 has a chamber housing 44, which is made from a conductive material and is grounded. In this chamber housing 44, a loading/unloading opening 44a is formed to load the stack 35 into its inside and to unload the stack 35 from its inside.

In this loading/unloading opening 44a, a gate valve 46 is disposed. This gate valve 46 can interrupt or establish communication between an internal space and an external space of the chamber housing 44. In the chamber housing 44, a gas outlet 44b is also formed to evacuate the internal space.

This gas outlet 44b is in communication with an exhaust device 50 such as a vacuum pump through a piping 48 and the like. On an inner surface of the chamber housing 44, a support member 52 is disposed, and this support member 52 supports a table 54.

In an upper portion of the table 54, an electrostatic chuck (not depicted) is disposed. Inside the table 54, a disk-shaped electrode 54a is disposed at a location below the electrostatic chuck. This electrode 54a is connected to a radio frequency power supply 58 via a matcher 56.

A disk-shaped opening is formed in the chamber housing 44 at a location opposing an upper surface of the table 54, and in this opening, a gas ejection head 62 is disposed. The gas ejection head 62 is supported on the chamber housing 44 via a bearing 60. This gas ejection head 62 is made from a conductive material, and is connected to a radio frequency power supply 66 via a matcher 64.

Inside the gas ejection head 62, a hollow space (gas diffusion space) 62a is formed. An inner side portion (for example, a lower portion) of the gas ejection head 62, a plurality of gas delivery openings 62b are formed communicating the gas diffusion space 62a and an internal space of the chamber housing 44. In an outer side portion (for example, an upper portion) of the gas ejection head 62, two gas supply inlets 62c and 62d are formed to supply predetermined gases to the gas diffusion space 62a.

Through a piping 68a and the like, the gas supply inlet 62c is in communication with a gas supply source 70a that supplies, for example, a fluorocarbon gas such as C₄F₈ and/or a sulfur fluoride gas such as SF₆. Through a piping 68b and the like, on the other hand, the gas supply inlet 62d is in communication with a gas supply source 70b that supplies, for example, an inert gas such as Ar and an O₂ gas.

When the first removal step S2 is performed in the dry etching system 42, what is called the Bosch process is conducted, for example. Described specifically, in this first removal step S2, the stack 35 on which a mask 37 is disposed so as to cover the devices 13 is first loaded into the internal space of the chamber housing 44 through the loading/unloading opening 44a, and is placed on the table 54 with the support substrate 33 located below the workpiece 11.

Next, the communication between the internal space and the external space of the chamber housing 44 is interrupted by the gate valve 46, and the stack 35 is held by the electrostatic chuck of the table 54. The internal space of the chamber housing 44 is then evacuated to a vacuum by the exhaust device 50.

Then, over a predetermined period of time, an SF₆-containing gas is supplied to the internal space of the chamber housing 44 from the gas supply source 70a, and with an Ar gas being supplied from the gas supply source 70b, radio frequency power is supplied to the gas ejection head 62 from the radio frequency power supply 66. As a consequence, the workpiece 11 is isotropically etched at portions thereof, which are exposed without being covered by the mask 37, with F-containing radicals and the like produced in the internal space of the chamber housing 44.

Subsequently, over a predetermined period of time, a C₄F₈-containing gas is supplied to the internal space of the chamber housing 44 from the gas supply source 70a, and with the Ar gas being supplied from the gas supply source 70b, radio frequency power is supplied to the gas ejection head 62 from the radio frequency power supply 66. As a consequence, CF radicals are allowed to deposit on the etched portions of the workpiece 11, and protective films of fluorocarbon are formed there.

Afterwards, over a predetermined period of time, with the SF₆-containing gas being supplied from the gas supply source 70a and the Ar gas being supplied from the gas supply source 70b, to the internal space of the chamber housing 44, radio frequency power is supplied to the electrode 54a disposed inside the table 54 from the radio frequency power supply 58, and radio frequency power is supplied to the gas ejection head 62 from the radio frequency power supply 66. As a consequence, F-containing ions and the like produced in the internal space of the chamber housing 44 are accelerated toward the table 54, so that the protective films are anisotropically etched. Concomitantly with this etching, the portions of the workpiece 11, which are not covered by the mask 37, are again exposed and further etched.

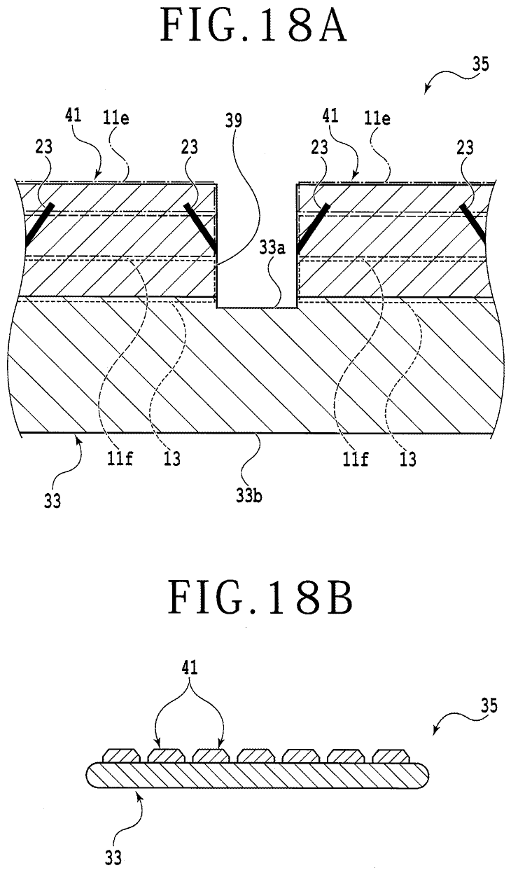

In the first removal step S2 of the method according to the second embodiment, the above-mentioned isotropic etching and formation and anisotropic etching of protective films are repeated further until grid-patterned grooves are formed through the workpiece 11 with their bottom surfaces positioned in the support substrate 33 (see FIG. 18A). FIG. 18A is an enlarged fragmentary cross-sectional view schematically depicting a portion of the stack 35 in which one of the grooves has been formed.

Concomitantly with the isotropic etching and anisotropic etching, the first to-be-removed portions 11d are removed along with the modified regions 21 and cracks 23 included in the first to-be-removed portions 11d. However, portions of the cracks 23, the portions spreading from the first to-be-removed portions 11d and being formed in the intermediate portions 11f and the second to-be-removed portions 11e, are allowed to remain. By the foregoing, the first removal step S2 is completed.

After the first removal step S2, a second removal step S3 is performed. FIG. 18B is a cross-sectional view schematically depicting the stack 35 manufactured in the second removal step S3 of the method according to the second embodiment and including a plurality of chips 41.

This second removal step S3 is performed, for example, in the grinding machine 30 by grinding the sides of the back surfaces of the chips 41 until the second to-be-removed portions 11e are removed. It is to be noted that this grinding is performed as in the above-mentioned second removal step S3 of the method according to the first embodiment, and its detailed description is hence omitted.

When the sides of the back sides of the chips 41 are ground until the cracks 23 are exposed at the back surfaces of the respective chips 41, the chips 41 are cleaved using the cracks 23 as boundaries. In other words, back surface side peripheral edge portions of the respective chips 41 are separated from the individual chips 41 during this grinding. By the foregoing, the second removal step S3 is completed.

It is to be noted that the constructions, methods, and the like according to the above-mentioned first and second embodiments can be practiced with changes or modifications made as appropriate to such extent as not departing from the scope of the object of the present invention.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A method for manufacturing a plurality of chips by removing, from a workpiece with a plurality of devices formed on a side of a front surface thereof, first to-be-removed portions located around the respective devices and second to-be-removed portions located on a side of a back surface of the workpiece with respect to the respective devices, the chips being thinner than the workpiece, the method comprising:
an internal processing step of irradiating the first to-be-removed portions with a laser beam of a wavelength having transmissivity for the workpiece to form a plurality of modified regions located in the first to-be-removed portions, respectively, and a plurality of cracks spreading from the modified regions, respectively, so that each crack reaches corresponding one of the second to-be-removed portions through corresponding one of intermediate portions located between the devices and the second to-be-removed portions;
a first removal step of, after the internal processing step, removing the first to-be-removed portions; and
a second removal step of, after the first removal step, grinding and removing the second to-be-removed portions and using the cracks as boundaries to separate, from the chips, back surface side peripheral edge portions thereof.

2. The method according to claim 1, wherein,
in the internal processing step, the laser beam is split to form a plurality of focal points, and
the workpiece is irradiated with the laser beam such that the focal points are formed at locations different from one another in corresponding one of a thickness direction of the workpiece and directions orthogonal to the thickness direction.

3. The method according to claim 2, further comprising:
before the internal processing step, after the internal processing step and before the first removal step, or after the first removal step and before the second removal step, a bonding step of bonding the devices to a support substrate such that the second to-be-removed portions are exposed.

4. The method according to claim 1, further comprising:
before the internal processing step, after the internal processing step and before the first removal step, or after the first removal step and before the second removal step, a bonding step of bonding the devices to a support substrate such that the second to-be-removed portions are exposed.
